(19) United States
(12) Patent Application Publication
(10) Pub. No.: US 2010/0142167 A1
(43) Pub. Date: Jun. 10, 2010

(54) ELECTRONIC, IN PARTICULAR MICROELECTRONIC, FUNCTIONAL GROUP AND METHOD FOR ITS PRODUCTION

(75) Inventor: Norman Marenco, Hohenaspe (DE)

Correspondence Address: SCHWEGMAN, LUNDBERG & WOESSNER, P.A., P.O. BOX 2938, MINNEAPOLIS, MN, 55402, US

(73) Assignee: Fraunhofer-Gesellschaft zur Forderung der Angewandten Forschung E.V., Munchen (DE)

(21) Appl. No.: 12/515,804

(22) PCT Filed: Nov. 24, 2006
(86) PCT No.: PCT/EP2006/011515

§ 371 Date: Jan. 19, 2010

(51) Int. Cl. H05K 7/00; B32B 37/12; B32B 38/14

(52) U.S. Cl. 361/760; 156/60; 156/277; 156/241

(57) ABSTRACT

An electronic, in particular microelectronic, functional group and to a method for its production are described. The method can include the following steps: a) coating of a mount with a non-conductive adhesive; b) application of a conductor structure to a subarea of the adhesive layer; c) arrangement of an electronic component with at least one external electrical connecting contact on the adhesive layer and on the conductor structure, with the at least one connecting contact of the electronic component being brought directly into contact with the conductor structure, and with a part of the outer casing of the component being brought directly into contact with the adhesive layer. The method can allow electronic, in particular microelectronic, functional groups to be produced with care, quickly and in particular at low cost.

The invention relates to an electronic, in particular a microelectronic, functional group and a method for the production of such a functional group.

An electronic functional group generally contains at least one or more electronic components, a conductor structure which contacts the electronic components and a carrier on which electronic components and conductor structure are applied.

In order to connect an electronic component, in particular a microelectronic component, such as for example a chip, electrically to the conductor structure and to mount it on the carrier, various methods are known:

It is known, on the one hand, to dispose chips with their electrical connection contacts on a conductor structure applied on a carrier and, by introducing energy, for example by means of heat, ultrasound or pressure, to produce an integral joint between the metal contacts of the chip and the assigned contacts of the conductor structure.

Another possibility is to configure the conductor structure at least in regions by an isotropically conductive adhesive, to place the chip on this region and then to let the adhesive set.

It is known furthermore to coat a chip on the contact side over the entire surface with an anisotropically conductive adhesive, the adhesive containing a small proportion of metal balls or metallically coated balls. The chip is pressed onto a substrate and a conductor structure configured there. The statistical distribution of the balls ensures that, when pressing the chip onto the substrate, a sufficient number of balls is always present in the region of the contact surfaces. Due to the high contact pressure and the shrinkage during setting of the adhesive, the contacts remain connected frictionally to each other. On the other hand, insufficient metal balls are available for electrical conduction for formation of undesired electrical bridges with further contacts.

As an alternative, also non-conductive adhesive can be used. The connection contacts of the chip are configured in this case as conductive bumps. Due to sufficiently high contact pressure and by setting and shrinkage of the adhesive, the direct contact of the conductive bumps with the conductor structure is produced and maintained.

A disadvantage of the above methods is that these either greatly load the electronic components thermally and/or mechanically or produce a mechanically inadequate connection between component and carrier. In the latter case, further measures are necessary in order to ensure the mechanical mounting of the component, as a result of which however the methods become more complex. A further disadvantage of the mentioned methods is that these require partially electrically conductive adhesives, however an adhesive of this type is relatively expensive and unsuitable for a good many applications because of its dielectric properties.

It is hence the object of the present invention to produce an electronic, in particular microelectronic, functional group which ensures a stable contact of component with conductor structure and carrier, can be produced with low complexity and costs whilst protecting the components, in particular no conductive adhesives are required. It is a further object of the invention to produce a method for the production of such a functional group.

These objects are achieved by a functional group and a method for the production of a functional group according to the independent claims.

Advantageous developments are described in the dependent claims.

The invention produces an electronic, in particular microelectronic, functional group, containing a planar first carrier, a first adhesive layer comprising a non-conductive adhesive which is applied on the carrier, a conductor structure which is applied on the side orientated away from the carrier on a partial region of the adhesive layer and at least one electronic component, in particular a microelectronic chip, with at least one externally situated electrical connection contact, the at least one connection contact of the electronic component being in direct contact with the conductor structure and a part of the outer shell of the component being in direct contact with the adhesive layer. There is understood by externally situated contact each contact of the component which is accessible from outside and which is intended to be contacted by the conductor structure.

According to the invention, the non-conductive adhesive layer is used for mechanical fixing of the electronic component.

Adhesives of this type are available economically. This makes it possible in particular to apply the adhesive over the entire surface on the surface of the carrier as a layer, which lowers the complexity and hence process costs since special structuring of the adhesive is not required. Furthermore, the poor dielectric properties of an anisotropically conductive adhesive and also a resistance of an isotropically conductive adhesive which is possibly too high are avoided.

By using adhesive which is not set or only at low temperatures, thermal loading of the electronic component can be avoided. Since no high contact pressures are required for the production of an electrical contact between component and conductor structure, as when using anisotropically conductive adhesive, the mechanical loading can also be kept low.

The conductor structure is preferably configured directly on the adhesive layer.

Carrier, adhesive layer, conductor structure and/or the at least one electronic component can be mechanically rigid or flexible.

The use of flexible elements, in particular a flexible carrier, makes it possible to produce a flexible electronic functional group. A flexible functional group of this type is suitable in particular in use as so-called “smart label”, there being understood thereby labels which are equipped with a chip and an antenna and hence are able to transmit a high-frequency identification signal when activated.

Also a rigid, bending-resistant construction of the functional group is fundamentally possible.

Further fields of application are opened up in the field of polymer electronics, for example for RFID applications, such as smart labels, e-paper and general flexible displays which can be used for example in bonus cards, such as telephone cards, customer discount systems and the like.

There can be used as carriers for example paper, cardboard, polymer films or printed circuit boards, depending upon whether a flexible or bending-resistant construction is intended to be achieved.

There can be used as adhesive for example acrylates, polysiloxanes, epoxides, thermoplastics, possibly with a suitable surface treatment.

The conductor structure can be formed by applying silver ink or conductive paste.

An advantageous development of the invention provides that the functional group has a second adhesive layer comprising a non-conductive adhesive and a planar second carrier, which form with first adhesive layer and first carrier a solid layer composite first carrier-first adhesive layer-second adhesive layer-second carrier, the conductor structure and/or the at least one electronic component being situated at least in regions between first and second carrier.

In this way, it is possible, on the one hand, to stabilise the electronic component and/or conductor structure mechanically and, on the other hand, these two elements can be well protected mechanically by such a “sandwich” construction.

Preferably, conductor structure and the at least one electronic component are situated partially or completely between first and second adhesive layer, in particular are embedded in the adhesive layer.

The two adhesive layers are preferably completely covered by the carriers on the upper and lower side.

Preferably, the adhesives of the first and second adhesive layer are identical. This ensures a good integral joint between the layers.

It is also possible to provide the second adhesive layer, analogously to the first adhesive layer, with a conductor structure and to contact electronic components with the latter, thus for example in order to apply an electrically insulated bridge across the windings of an antenna coil.

Furthermore, the invention produces a method for the production of an above-described electronic functional group, containing the steps:
a) coating of a carrier with a non-conductive adhesive;
b) application of a conductor structure on a partial region of the adhesive layer;
c) arrangement of an electronic component with at least one externally situated electrical connection contact on the adhesive layer and on the conductor structure, the at least one connection contact of the electronic component being brought in direct contact with the conductor structure and a part of the outer shell of the component being brought in direct contact with the adhesive layer.

In particular light pressing of the electronic component suffices to produce a good electrical contact between the connection contact of the component and the conductor structure and also to connect the component adhesively to the adhesive layer. Preferably, the adhesive layer is configured to be sufficiently large-surface in order to offer the electronic component a sufficiently large contact surface.

A frictional connection between connection contact of the component and conductor structure is adequate for ensuring an electrical connection for most applications. In this case, the mounting of the electronic component can be effected without high mechanical and thermal loading of the component. This is advantageous in particular if sensitive components, such as for example microelectronic chips, are being mounted.

Alternatively, it is also possible that the at least one electrical connection contact of the component is connected, in a further step, to the region of the conductor structure which contacts said contact electrically, by means of a thermal treatment. In this way, a readily conductive intermetallic phase is formed.

It is possible to apply the method according to the invention within a roll-to-roll process, i.e. in a continuous process. This is possible in particular in that adhesives can be used which do not require subsequent setting in a separate furnace. The method according to the invention can be implemented in a time cycle lasting a few seconds. It is hence advantageous in particular for the production of electronic functional groups, such as for example the above-mentioned “smart labels”, which must be able to be produced in large numbers and with low cost in order to be of economic interest.

In addition to a roll-to-roll process, it is of course likewise possible to construct the method as roll-to-sheet material or sheet-to-sheet material. The latter is possible in particular if bending-resistant functional groups are intended to be produced.

An advantageous development of the invention provides that, in a further step, the first adhesive layer and preferably also the component which is disposed on the first adhesive layer and/or the conductor structure is or are coated at least in regions with a further non-conductive adhesive, and a further carrier is disposed on this second adhesive layer.

This can be effected in particular by lamination of the carrier which is fitted with the conductor structure, at least one electronic component and adhesive layer. The method can likewise be produced advantageously in that firstly the further carrier is coated with the second adhesive layer in order only then to be brought in its entirety by a lamination process onto the first adhesive layer or onto the latter with applied component and/or conductor structure.

The conductor structure can be applied for example by means of an ink jet printing method directly on the surface of the adhesive layer. Another possibility is firstly to configure the conductor structure on the surface of a substrate and, by placing the substrate on the adhesive layer of the conductor structure, to transfer it from said substrate onto the adhesive layer.

The invention is now explained in more detail with reference to an embodiment which is represented by several Figures. There are thereby shown

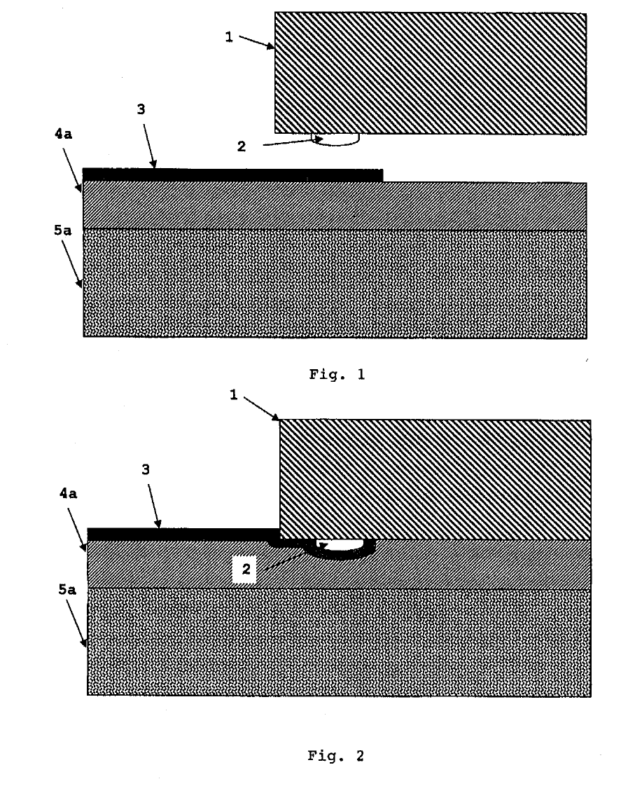

FIG. 1 an embodiment of the functional group according to the invention in the state briefly before contacting of the electronic component with conductor structure and adhesive layer,

FIG. 2 the method in the state after contacting of the component with conductor structure and adhesive layer, and

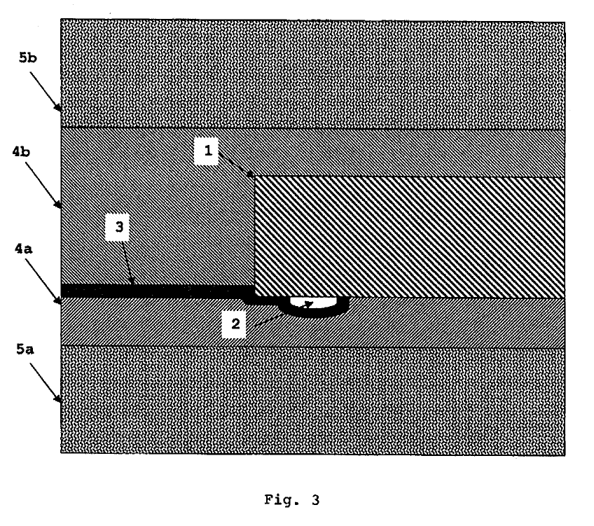

FIG. 3 a further embodiment of the electronic functional group according to the invention after completion of the production method.

According to one embodiment of the method according to the invention, firstly a planar carrier 5a, here a sheet of paper with a thickness of 200 micrometres, is coated uniformly on one side on the total surface with a non-conductive adhesive, here acrylate, so that a first adhesive layer 4a with a thickness of 20 micrometres is formed. A silver ink in the form of a previously defined conductor structure 3 is applied on a partial region of the adhesive layer 4a by means of an ink jet printing method.

FIG. 1 shows this process state, shortly before an electronic component, here an RFID chip 1 with an externally situated electrical connection contact 2, is disposed on the conductor structure 3 and adhesive layer 4a.

The chip 1 with an externally situated electrical connection contact 2, which is configured for example in the form of a bump, but which can also have other configurations, is disposed on the adhesive layer 4a and on the conductor structure 3, the connection contact 2 being brought in direct contact with the conductor structure 3 and a part of the outer shell of the component 1 is brought in direct contact with the adhesive layer. In order to ensure a good frictional connection between connection contact 2 and conductor structure 3 and also a good adhesive connection between outer shell and adhesive layer 4a, the chip 1 is pressed lightly in the direction of the carrier 5a.

FIG. 2 shows this state of the method.

A second layer comprising non-conductive adhesive, here likewise acrylate, is applied on the free surface regions of the first adhesive layer 4a, on the conductor structure 3 and on the free surface of the chip 1. This second adhesive layer 4b is sealed on the upper side thereof with a second carrier 5b, here likewise a sheet of paper with a wall thickness of 200 micrometres (FIG. 3).

Conductor structure 3 and chip 1 are hence completely embedded in the adhesive layers 4a and 4b. They are mechanically protected by the externally situated carrier layers 5a and 5b. The flexible carriers made of paper, the thin adhesive layers 4a, 4b and the thin conductor structure 3 ensure that the electronic functional group is overall flexible. The chip itself has low flexibility; however it is very small relative to possible bending radii of the carrier layers 5a and 5b. Also local reinforcement can be desired according to requirements.

In this embodiment, the electronic functional group forms a so-called “smart label”. The RFID chip is able to transmit high-frequency electromagnetic signals for identification. The conductor structure 3 is configured in this respect as transmitting- and receiving antenna for the chip 1.

As an alternative to the embodiment described here, it is possible in particular to use bending-resistant elements, in particular bending-resistant carriers. Furthermore, it is also possible to transfer conductor structure 3 and connection contact 2 of the electronic component into an intermetallic phase by means of thermal treatment. In addition, the carriers can be provided in a separate process with adhesive layers and also with a conductor structure.

The method represented here is suitable in particular for the production of “smart labels”. It uses material exclusively which is already present and reduces the process steps which are required for the mounting and connecting technics to a minimum. The production can be effected extremely economically and with an optimised throughput, for example via a roll-to-roll process with possible subsequent setting phase, e.g. as an entire roll or as sheet material at room temperature or in a heated cabinet. In addition, the method can be implemented in a protective manner with low mechanical loading.

1. An apparatus comprising:
an electronic, in particular microelectronic, functional group comprising:
a planar first carrier;
a first adhesive layer comprising a non-conductive adhesive that is applied on the first carrier;
a conductor structure that is applied on a partial region of the first adhesive layer that is oriented away from the first carrier; and
at least one electronic component comprising a microelectronic chip, the electronic component comprising at least one externally situated external connection contact that is in direct contact with the conductor structure, and a part of an outer shell of the electronic component being in direct contact with the first adhesive layer.

2. The apparatus of claim 1, wherein the functional group comprises a second adhesive layer comprising a non-conductive adhesive and a planar second carrier, which form with first adhesive layer and first carrier a solid layer composite first carrier-first adhesive layer-second adhesive layer-second carrier, wherein the conductor structure and/or the at least one electronic component being situated at least in a region between the first and second carriers.

3. The apparatus of claim 2, wherein at least one of the first and second carriers, at least one of the first and second adhesive layers, the conductor structure, and/or the at least one electronic component is or are flexible.

4. A method comprising:
coating a carrier with a nonconductive adhesive;
applying a conductor structure on a partial region of the adhesive layer;
arranging an electronic component with at least one externally situated electrical connection contact on the adhesive layer and on the conductor structure;
bringing the at least one electrical connection contact of the electronic component in direct contact with the conductor structure; and
bringing a part of an outer shell of the electronic component in direct contact with the adhesive layer.

5. The method of claim 4, further comprising:
coating with a further non-conductive second adhesive layer, at least in a region, the first adhesive layer and the electronic component that is disposed on the conductor structure and on the first adhesive layer and/or the conductor structure; and
disposing a further carrier on the second adhesive layer.

6. The method of claim 5, further comprising connecting, by thermally treating, the at least one electrical connection contact of the electronic component to a region of the conductor structure that electrically contacts the electrical connection contact.

7. The method of claim 6, wherein applying the conductor structure comprises using at least one of ink jet printing, screen printing, spraying, or transferring from a substrate onto the first adhesive layer.

8. The apparatus of claim 1, wherein the first carrier, the first adhesive layer, the conductor structure, and/or the at least one electronic component is or are flexible.

9. The method of claim 4, further comprising connecting, by thermally treating, the at least one electrical connection contact of the electronic component to a region of the conductor structure that electrically contacts the electrical connection contact.

10. The method of claim 5, wherein applying the conductor structure comprises using at least one of ink jet printing, screen printing, spraying, or transferring from a substrate onto the first adhesive layer.

11. The method of claim 4, wherein applying the conductor structure comprises using at least one of ink jet printing, screen printing, spraying, or transferring from a substrate onto the first adhesive layer.

12. The method of claim 4, wherein applying the conductor structure comprises using ink jet printing.

13. The method of claim 4, wherein applying the conductor structure comprises using screen printing.

14. The method of claim 4, wherein applying the conductor structure comprises using spraying.

15. The method of claim 4, wherein the applying the conductor structure comprises transferring from a substrate onto the first adhesive layer.
